(19) United States
(12) Patent Application Publication
(10) Pub. No.: US 2004/0099957 A1
(43) Pub. Date: May 27, 2004

(54) Integrated circuit devices including low dielectric side wall spacers and methods of forming same

(76) Inventor: Beom-jun Jin, Seoul (KR)

Correspondence Address: MYERS BIGEL SIBLEY & SAJOVEC, PO BOX 37428, RALEIGH, NC, 27627, US

(21) Appl. No.: 10/689,981

(22) Filed: Oct. 21, 2003

(30) Foreign Application Priority Data
Nov. 22, 2002 (KR) 02-73053

(51) Int. Cl. H01L 23/48

(52) U.S. Cl. 257/774

(57) ABSTRACT

An integrated circuit device can include a conductive contact in a hole in an interlevel dielectric layer with a first spacer, having a first dielectric constant, on a side wall of the conductive contact. A second spacer having a second dielectric constant, that is less than the first dielectric constant, is located between the first spacer and the side wall of the conductive contact. Accordingly, the higher dielectric (first) spacer can be separated from a junction of a contact pad and a conductive contact, thereby reducing the likelihood that remnant higher dielectric material is, left on the contact pad, which could otherwise increase parasitic capacitance of the integrated circuit device. Related methods are also disclosed.

### CLAIM FOR PRIORITY

This application claims the priority of Korean Patent Application No. 2002-73053 filed Nov. 22, 2002, in the Korean Intellectual Property Office, the disclosure of which is incorporated herein in its entirety by reference.

### FIELD OF THE INVENTION

The invention relates to integrated circuit devices and methods of fabricating the same, and more particularly, to integrated circuit devices having side wall spacers and methods of fabricating the same.

### BACKGROUND

Integrated circuit devices are continuously being reduced to smaller sizes. Such reductions in the size of an integrated circuit device can include reductions in the distance between adjacent contacts, as well as in the size of the contacts themselves. In general, a contact can be made by forming an interlevel dielectric layer on either a substrate or a material layer including a lower conductive pattern, and patterning the interlevel dielectric layer using a photolithographic process so as to form a contact hole that exposes the lower conductive pattern.

Next, a conductive material (such as polysilicon or metal) is used to fill the contact hole. In this case, the remaining interlevel dielectric layer can also be covered with the conductive material. Then, an etch back or chemical mechanical polishing (CMP) can be performed on the resultant structure in order to remove the excess conductive material and to planarize the interlevel dielectric layer, thereby forming a contact within the interlevel dielectric layer. However, if the contact hole is not completely filled with the conductive material, a seam may form in the contact.

As the size of the contact and the distance between adjacent contacts becomes reduced, electrical shorts between adjacent contacts may occur if all of the excess conductive material is not removed. The shorts between the adjacent contacts may cause malfunctions in the integrated circuit elements connected to the adjacent contacts.

Some of the problems discussed above can be addressed by forming contact spacers on the side walls of the contacts using, for example, silicon nitride. FIG. 1 is a plan view of a conventional integrated circuit device including contact spacers. FIG. 2 is a cross-sectional view of the integrated circuit device of FIG. 1, taken along the line I-I′. In FIG. 1, the illustration of a third interlevel dielectric layer, which corresponds to reference numeral 140 of FIG. 2, is omitted to show planar arrangement of the integrated circuit device.

A contact plug and a contact pad can be considered to be different types of contacts. However, in this disclosure, a lower contact and an upper contact will be referred to as “contact pads” and “contact plugs”, respectively, to avoid possible confusion in cases where the lower contact is formed directly on the upper contact.

Referring to FIGS. 1 and 2, a first interlevel dielectric layer 110 is formed on a substrate 100. A contact pad 115 is formed in the first interlevel dielectric layer 110, and a gate line pattern (not shown) may be further included in the first interlevel dielectric layer 110. A second interlevel dielectric layer 120 is formed on the first interlevel dielectric layer 110. A bit-line contact plug may be further included in the second interlevel dielectric layer 120.

A third interlevel dielectric layer 140 is formed on the second interlevel dielectric layer 120, and a conductive line pattern 130, which is a bit line pattern, may be included in the third interlevel dielectric layer 140. The third interlevel dielectric layer 140 is formed such that a contact plug 160 is connected to the contact pad 115.

Contact spacers 150, which are made of silicon nitride, are located on the side walls of each contact plug 160, i.e., between the contact plug 160 and the third interlevel dielectric layer 140. Each contact spacer 150 can prevent the occurrence of electrical shorts between adjacent contact plugs 160 and between the contact plugs 160 and the conductive line patterns 130.

A conventional method of fabricating the contact spacers 150 will now be discussed. First, a contact hole is formed in the interlevel dielectric layer. Next, a silicon nitride layer is formed to a predetermined thickness on the interlevel dielectric layer and in the contact hole. After the formation of the silicon nitride layer, the silicon nitride layer on the upper surface of the interlevel dielectric layer and in the contact hole is etched to remove the interlevel dielectric layer from the upper surface of the interlevel dielectric layer while a portion of the silicon nitride layer in the contact hole is left remaining on the side walls to form the contact spacers 150. Next, the contact hole is filled with a conductive material and the resulting structure is planarized so as to form contact plug 160. A precleaning process may be performed before the contact hole is filled with the conductive material to remove impurities or a natural oxide layer.

However, the silicon nitride layer may not be completely removed when forming the spacers 150. In particular, if the silicon nitride layer is not completely removed and remains on the bottom of the contact plug 160 (which contacts the contact pad 115) a contact resistance of the contact plug 160 can be increased, and as a result, the performance of a integrated circuit device may be reduced.

Furthermore, the above problems may become more serious if a seam S is formed in the contact pad 115 below the contact plug 160. The contact pad 115 is formed of a conductive material such as polysilicon, using low-pressure chemical vapor deposition (LPCVD) having excellent step coverage. In this case, if the pattern size is large, a seam may be less likely to form in the contact pad 115. However, if the size of the pattern is reduced, it may be more likely that the contact hole is not completely filled with the conductive material, and thus, a seam can be more easily formed in the contact.

If a seam is formed in the contact pad 115, the seam may be filled with the silicon nitride during the formation of the silicon nitride layer, which may be difficult to remove during the etching process used to form the spacers. Thus, it may be likely that the silicon nitride material may remain in the seam, which can increase the contact resistance of the contact pad 115 and the overall resistance of the contact plug/pad structure.

Furthermore, using silicon nitride to form the spacers may adversely affect operation of the resulting structure by increasing the parasitic capacitance associated with a bit line. In particular, silicon nitride has a dielectric constant of about 7, whereas silicon oxide has a dielectric constant of about 3.9, that is, the dielectric constant of the silicon nitride can be much higher than that of silicon oxide. Thus, a signal on a bit line adjacent to contact spacers of silicon nitride may be delayed due to an increased RC constant provided by the silicon nitride spacers.

### SUMMARY

Embodiments according to the invention can provide low dielectric spacers in integrated circuit devices and methods of forming the same. Pursuant to these embodiments, an integrated circuit device can include a conductive contact in a hole in an interlevel dielectric layer with a first spacer, having a first dielectric constant, on a side wall of the conductive contact. A second spacer having a second dielectric constant, that is less than the first dielectric constant, is located between the first spacer and the side wall of the conductive contact. Accordingly, the higher dielectric (first) spacer can be separated from a junction of a contact pad and a conductive contact, thereby reducing the likelihood that remnant higher dielectric material is left on the contact pad, which could otherwise increase parasitic capacitance of the integrated circuit device.

In some embodiments according to the invention, the first spacer can be silicon nitride and the second spacer can be silicon oxide. In some embodiments according to the invention, the thickness of the first spacer is in a range between about 10 Å and about 300 Å. In some embodiments according to the invention, the thickness of the second spacer is in a range between about 10 Å and about 200 Å.

In some embodiments according to the invention, the integrated circuit device can further include a conductive line in the interlevel dielectric layer that is adjacent to the first spacer and is opposite the conductive contact.

According to method embodiments of the invention, an integrated circuit device can be formed by forming a first spacer having a first dielectric constant on a side wall of an interlevel dielectric layer that defines a contact hole in the interlevel dielectric layer. A second spacer having a second dielectric constant that is greater than the first dielectric constant can be formed on the first spacer and a conductive contact can be formed in the hole.

In some embodiments according to the invention, an integrated circuit device can be further formed by removing a portion of the second spacer from a bottom of the hole to expose the first spacer, wherein a remnant portion of the first spacer remain at the bottom. The remnant portion and the first spacer can be removed from the bottom to expose an underlying contact pad.

In some embodiments according to the invention, the first spacer comprises silicon nitride and the second spacer comprises silicon oxide. In some embodiments according to the invention an integrated circuit device can be further formed by forming a conductive line in the interlevel dielectric layer adjacent the first spacer opposite the second spacer.

### BRIEF DESCRIPTION OF THE DRAWINGS

FIG. 1 is a schematic plan view of a conventional integrated circuit device including contact spacers.

FIG. 2 a schematic cross-sectional view of the conventional integrated circuit device of FIG. 1, taken along the line I-I′.

FIG. 3 is a schematic cross-sectional view illustrating embodiments of integrated circuit devices having double contact spacers according to the invention.

FIG. 4 is a schematic plan view illustrating embodiments of integrated circuit devices having double contact spacers according to the invention

FIG. 5 is a schematic cross-sectional view illustrating embodiments of the integrated circuit devices of FIG. 4 taken along the line II-II′.

FIG. 6 is a schematic plan view illustrating embodiments of integrated circuit devices having double contact spacers according to invention.

FIG. 7 is a schematic cross-sectional view illustrating embodiments of the integrated circuit device of FIG. 6 taken along the line III-III′.

FIG. 8 is a schematic cross-sectional view illustrating embodiments of the integrated circuit device of FIG. 6, taken along the line IV-IV′.

FIGS. 9A through 9D are cross-sectional views illustrating method embodiments of fabricating integrated circuit devices having double contact spacers according to the invention.

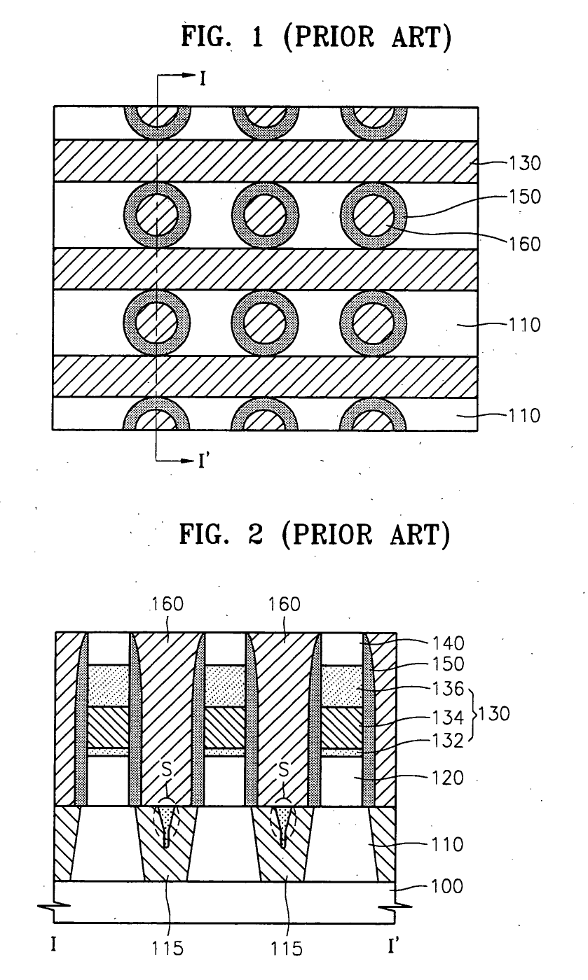

### DESCRIPTION OF EMBODIMENTS ACCORDING TO THE INVENTION

The present invention will now be described more fully hereinafter with reference to the accompanying drawings, in which embodiments of the invention are shown. Like numbers refer to like elements and repeated explanation of identical elements may be avoided with reference to subsequent figures in the specification. In the figures, certain features, layers or components may be exaggerated for clarity. When a layer is referred to as being “on” another layer or substrate, it can be directly on the other layer or substrate, or intervening layers, films, coatings and the like may also be present unless the word “directly” is used which indicates that the feature or layer directly contacts the feature or layer.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

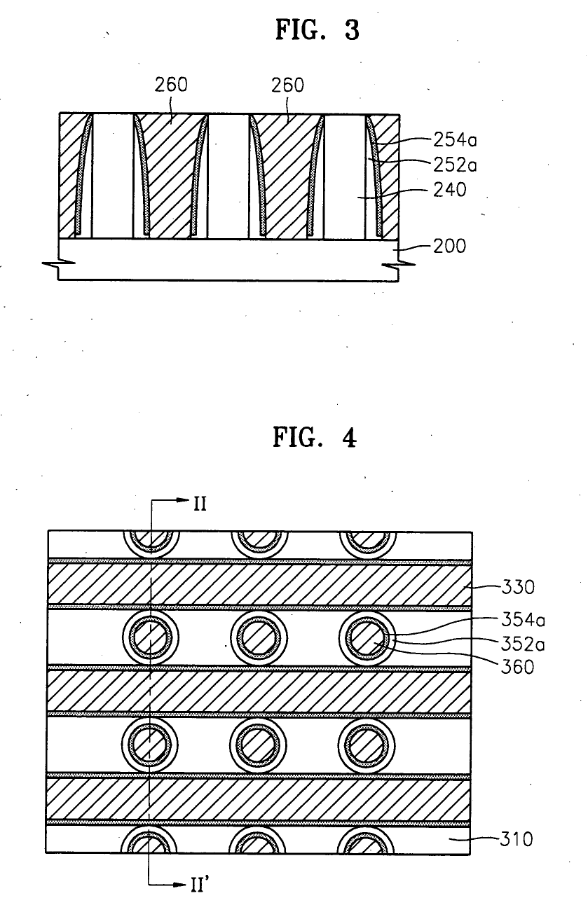

FIG. 3 is a schematic cross-sectional view of an integrated circuit device including double contact spacers, according to embodiments of the invention. Referring to FIG. 3, an interlevel dielectric layer 240 is formed on a substrate 200 and contacts 260 are formed in contact holes at predetermined positions in the interlevel dielectric layer 240. First and second contact spacers 252a and 254a are located on the side walls of the contacts 260 (i.e., between each of interlevel dielectric layer 240 and each of the contacts 260). In some embodiments according to the invention, the first contact spacer 252a is formed of silicon oxide and the second contact spacer 254a is formed of silicon nitride.

Each contact 260 may be directly on a particular portion of the substrate 200 such as source/drain regions (not shown) or a conductive pattern may be present between the source/drain regions and the contact 260. The contact 260 may be a portion of an interconnection which connects upper and lower conductors such as upper and lower interconnection lines.

The contact 260 can be formed of any conductive material. In some embodiments according to the invention, the contact 260 is formed of impurity-doped polysilicon or polysilicon, an upper portion of which can be coated with silicide. In some embodiments according to the invention, the contact 260 is formed of a metal material such as tungsten, copper, or aluminum. In some embodiments according to the invention, the first contact spacer 252a is formed to a thickness in a range between about 10 Å and about 200 Å, and the second spacer 254a is formed to a thickness in a range between about 10 Å and about 300 Å.

The first contact spacer (formed, for example, of silicon oxide) can have a lower dielectric constant than a dielectric constant of the second contact spacer (formed, for example, of silicon nitride). Therefore, the double contact spacer arrangement, shown for example, in FIG. 3, can have a smaller parasitic capacitance than a contact spacer that is formed of only silicon nitride.

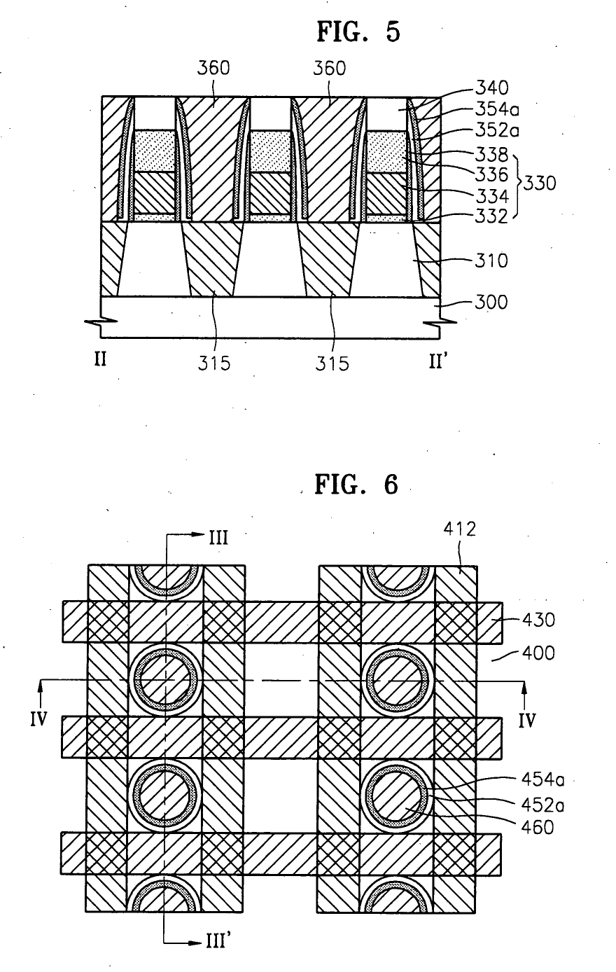

FIG. 4 is a schematic plan view illustrating integrated circuit devices having double contact spacers according to embodiments of the invention. FIG. 5 is a schematic cross-sectional view illustrating the integrated circuit device of FIG. 4, taken along the line II-II′. As described above, a second interlevel dielectric layer 340 is not illustrated in FIG. 4 to show the inner structure of an integrated circuit device more clearly.

Referring to FIGS. 4 and 5, a first interlevel dielectric layer 310 including a contact pad 315 is formed on a substrate 300. The contact pad 315 is formed of impurity-doped polysilicon or a conductive material, such as metal. A second interlevel dielectric layer 340, a conductive line pattern 330, and a contact plug 360, are formed on the first dielectric layer 310. In some embodiments according to the invention, another layer including a third conductive line pattern may be present between the first and second interlevel dielectric layers 310 and 340.

In some embodiments according to the invention, the conductive line pattern 330 is a gate line pattern or a bit line pattern, or an interconnection line pattern for electric interconnection. The inner structure of the conductive line pattern is not limited as shown in FIG. 4. For example, the conductive line pattern 330 can be a stacked structure of a titanium nitride (TiN) layer 332, a tungsten (W) layer 334, and a silicon nitride layer 336, or a stacked structure of a polysilicon layer, a tungsten silicide layer, and a silicon nitride layer.

In some embodiments according to the invention, spacers 338 are formed along the side walls of the conductive line pattern 330, as shown in FIG. 5. The second interlevel dielectric layer 340 may be formed to be level with or have a higher level than the conductive line pattern 330.

The contact plugs 360 are formed in contact holes in predetermined portions of the second interlevel dielectric layer 340 on the contact pads 315 between the conductive line patterns 330. Second and first contact spacers 354a and 352a are sequentially formed in the contact holes so that the contact spacers 354a and 352a are on the side walls of the contact plug 360. Materials for and thicknesses of the first and second contact spacers 352a and 354a may be the same as those of the first and second contact spacers 252a and 254a. The lengths of the first and second contact spacers 352a and 354a depend on that of the contact plug 360.

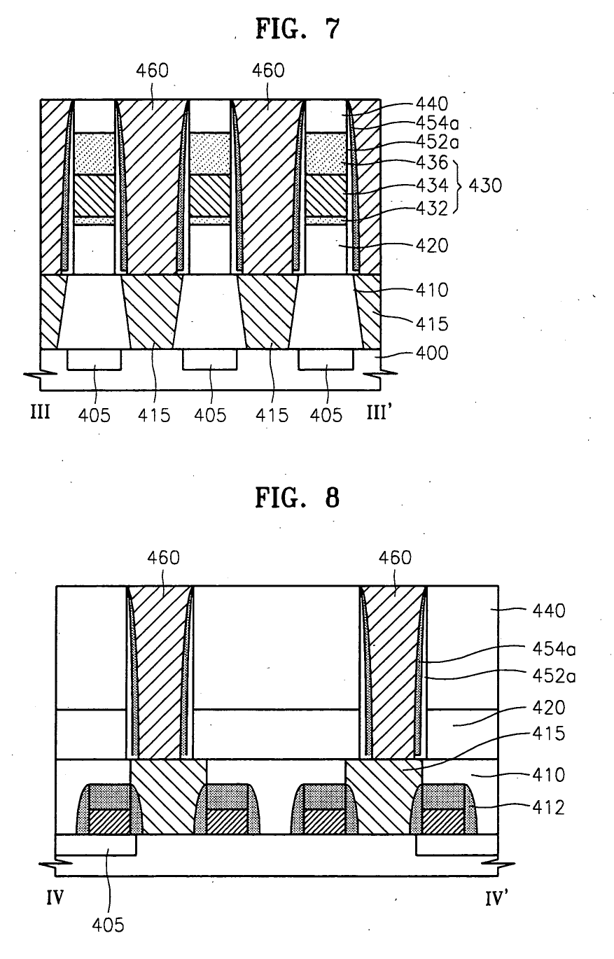

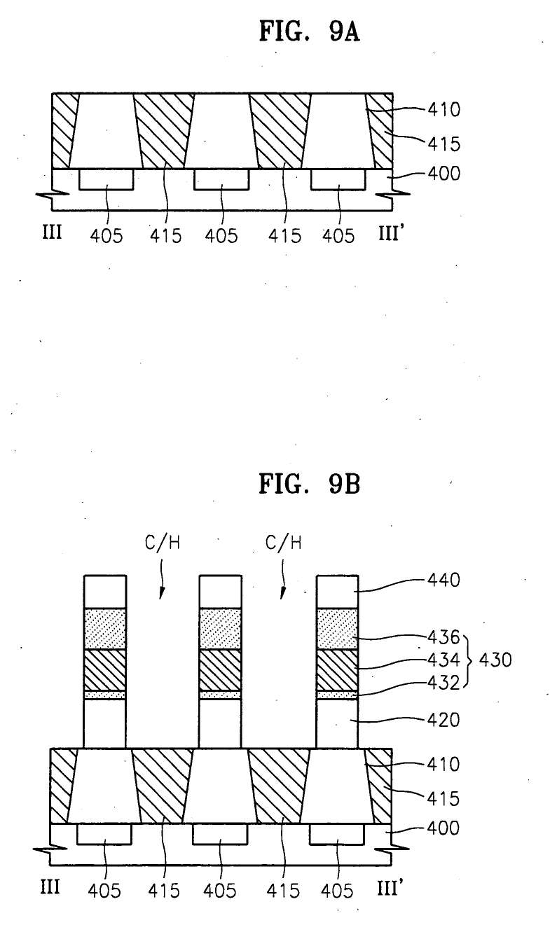

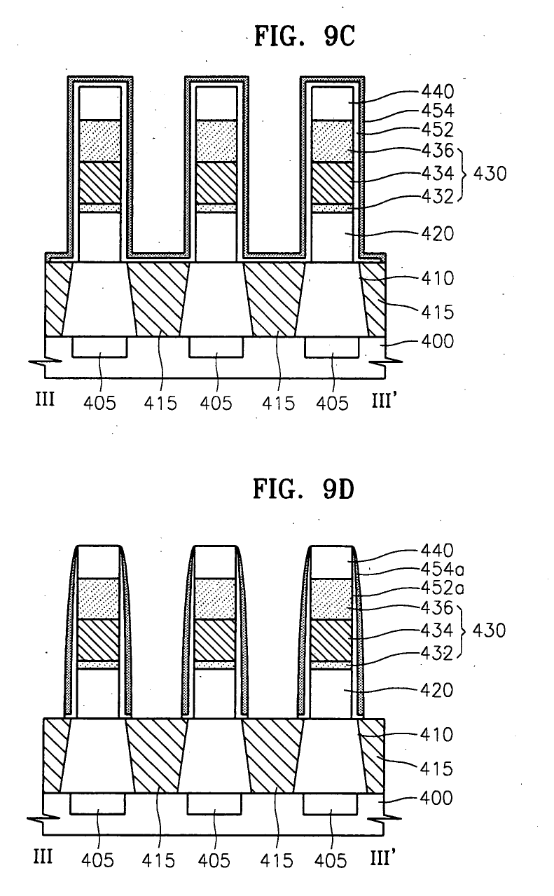

FIG. 6 is a schematic plan view illustrating integrated circuit devices having double contact spacers according to the invention. FIG. 7 is a schematic cross-sectional view illustrating the integrated circuit devices of FIG. 6, taken along the line III-III′. FIG. 8 is a schematic cross-sectional view illustrating the integrated circuit devices of FIG. 6, taken along the line IV-IV′. FIGS. 9A through 9D are cross-sectional views illustrating method embodiments of forming intermediate integrated circuit devices of FIG. 6, taken along the line III-III′, according to the invention.

Method embodiments of fabricating integrated circuit devices including double contact spacers according to the invention, are described herein with reference to FIGS. 9A through 9D and FIGS. 6 through 8. It will be understood that the invention is not limited to the embodiments of forming integrated circuit devices described herein and may be practiced according to other embodiments not specifically described herein.

Referring to FIGS. 6, 8, and 9A, field regions 405 are formed on a silicon substrate 400 to define active regions thereon, using a trench isolation method. Transistors, which include source/drain regions, and gate line patterns 412 are formed in and on the silicon substrate 400, respectively. A first interlevel dielectric layer 410 is formed on the resultant structure, a planarization process is performed on the first interlevel dielectric layer 410, and contact holes are formed in the first interlevel dielectric layer 410 using, for example, a photolithographic process. A conductive material is formed in the contact holes and on the first interlevel dielectric layer 410, and the resultant structure is planarized using etch back or chemical mechanical polishing (CMP), thereby obtaining contact pads 415 in the first interlevel dielectric layer 410.

Thereafter, referring to FIGS. 6, 8, and 9B, a second interlevel dielectric layer 420 is formed on the structure of FIG. 9A, bit line contact plugs (not shown) are formed in the second interlevel dielectric layer 420, and a bit line pattern 430 is formed on the resultant structure. The bit line contact plugs are connected to parts of the contact pads 415 and are electrically connected to the source/drain regions in the silicon substrate 400. The bit line pattern 430 may be a stacked structure of a titanium nitride layer 432, a tungsten layer 434, and a hard mask 436 of silicon nitride. Spacers may be formed along the side walls of the bit line pattern 430, using silicon nitride.

A third interlevel dielectric layer 440 is formed on the resultant structure. The third interlevel dielectric layer 440 need not necessarily have a higher level than the bit line pattern 430 as shown in FIG. 9B. A portion of the third interlevel dielectric layer 440 between the bit line patterns 430 is selectively etched to form contact holes that expose the contact pads 415. A mask having a hole-type pattern or a line-type pattern may be used to form the contact holes.

Referring to FIG. 9C, a silicon oxide layer 452 is deposited in the contact holes on the side walls of the second and third interlevel dielectric layers 420 and 440, and on the upper surface of the third interlevel dielectric layer 440. In some embodiments according to the invention, the silicon oxide layer 452 is formed to a thickness in a range between about 10 Å and about 200 Å using atomic layer deposition (ALD) or chemical vapor deposition (CVD).

A silicon nitride layer 454 is formed on the silicon oxide layer 452. In some embodiments according to the invention, the silicon nitride layer 454 is formed to a thickness in a range between about 10 Å and about 300 Å using ALD or CVD. As shown in FIG. 9C, an integrated circuit device is obtained in which the silicon oxide layer 452 and the silicon nitride layer 454 are formed on the side walls of the second and third interlevel dielectric layers 420 and 440, on the contact pads 415, and on the upper surface of the third interlevel dielectric layer 440. In some embodiments according to the invention, any seams in the surface of the contact pads 415 may be filled with the first formed silicon oxide layer 452.

Referring to FIG. 9D, an etching process is performed to form first and second contact spacers 452a and 454a. The silicon nitride layer 454 is selectively etched using an etching agent having excellent etching characteristics for etching silicon nitride, to obtain the second contact spacer 454a. The silicon oxide layer 452 is selectively etched using an etching agent having excellent etching characteristics for etching silicon oxide, to obtain the first contact spacer 452a. In some embodiments according to the invention, during the etching of the silicon oxide layer 452, the portion of the silicon oxide layer 452 on the contact pads 415 is entirely removed. If the contact pads 415 have seams with silicon oxide formed therein (as described above), a portion of the etched silicon oxide layer may remain in the seams.

In some conventional approaches, after the contact spacers are formed a further etching step is performed to eliminate any remnant silicon nitride, which is a by-product generated by the etching process. In contrast, in embodiments according to the invention, the silicon oxide layer 452, which is beneath the silicon nitride layer 254, is removed after forming the second contact spacers by etching the silicon nitride layer 454. That is, remnant silicon nitride can be removed during the etching of the silicon oxide layer 452.

Referring to FIG. 7, a precleaning process is performed on the resultant structure before forming contact plugs 460 in the contact holes, irrespective of whether the etching process of removing remnant silicon nitride is performed or not. In general, a silicon oxide layer, which can be naturally formed, and remnant impurities, which can be formed of a material other than silicon oxide, are eliminated through the precleaning process. The precleaning process can remove remnant silicon oxide generated during the formation of the first contact spacer 452a but not removed during the etching process described above, silicon oxide on the contact pads 451 or filled in seams, and natural silicon oxide layer and remnant impurities. Accordingly, in some embodiments according to the invention, the precleaning process is performed using a chemical composition including a material having excellent etching characteristics with respect to silicon oxide as a main gradient.

After the precleaning process, a conductive material is formed in the contact holes and a planarization process is performed on the resultant structure to form the contact plugs 460. The contact plugs 460 may be formed of impurity-doped polysilicon or a conductive material such as metal. Accordingly, as shown in FIG. 6, it is possible to fabricate an integrated circuit device in which the side walls of the third interlevel dielectric layer 440 are wrapped by the first contact spacers 452a, which are formed of silicon oxide, and the second contact spacers 454a, which are formed of silicon nitride, and the contact plugs 460, which are formed of a conductive material, are present between the third interlevel dielectric layer 440.

According to embodiments of the invention, insulating spacers can be formed around contacts, thereby preventing or reducing the likelihood of the occurrence of electrical shorts between adjacent contacts even if the distance between the contacts is reduced in an effort to provide a more highly integrated device. In some embodiments according to the invention, an integrated circuit device includes contact spacers formed of silicon oxide having a lower dielectric constant than silicon nitride. Accordingly, if seams exist in the contact pad or remnant impurities remain at an interface between the contact pad and a contact, the seams are filled with silicon oxide, which has a lower dielectric constant that other insulating materials, such as silicon nitride. Therefore, a double contact spacer that includes a contact spacer formed of silicon oxide (and remnant silicon oxide impurities) can provide an integrated circuit device with reduced parasitic capacitance compared to contact spacers formed of only silicon nitride and remnant silicon nitride impurities.

In addition, in a method of fabricating an integrated circuit device according to the invention, performing of a cleaning (or etching) process of eliminating remnant silicon nitride may be skipped. Also, remnant silicon oxide can be easily removed using a general precleaning process. In particular, using the precleaning process, it is possible to prevent silicon nitride from remaining in seams, thereby preventing an increase in resistance caused by impurities.

While the invention has been particularly shown and described with reference to preferred embodiments thereof, it will be understood by those skilled in the art that various changes in form and details may be made therein without departing from the spirit and scope of the invention as defined by the appended claims.

What is claimed:

1. An integrated circuit device comprising:
a conductive contact in a hole in an interlevel dielectric layer;
a first spacer having a first dielectric constant on a side wall of the conductive contact; and
a second spacer having a second dielectric constant that is less than the first dielectric constant located between the first spacer and the side wall of the conductive contact.

2. An integrated circuit device according to claim 1 wherein the first spacer comprises silicon nitride and the second spacer comprises silicon oxide.

3. An integrated circuit device of claim 1, wherein the thickness of the first spacer is in a range between about 10 Å and about 300 Å.

4. An integrated circuit device according to claim 1 wherein the thickness of the second spacer is in a range between about 10 Å and about 200 Å.

5. An integrated circuit device according to claim 1 further comprising:
a conductive line in the interlevel dielectric layer adjacent the first spacer opposite the conductive contact.

6. An integrated circuit device according to claim 1 further comprising:
a contact pad in a substrate, wherein the conductive plug contacts the contact pad.

7. An integrated circuit device according to claim 6 wherein the second spacer extends along the side wall to contact the contact pad; and
wherein the first spacer does not contact the spaced isolated from the contact pad.

8. An integrated circuit device comprising:
a substrate;
a first interlevel dielectric layer which is formed on the substrate, wherein contact holes are formed in the first interlevel dielectric layer;
first contact spacers which are formed along the side walls of the first interlevel dielectric layer which is exposed via the contact holes, the first contact spacers being formed of silicon oxide;
second contact spacers which are formed of silicon nitride and formed on the first spacer; and
contact plugs which are formed between the second contact spacers.

9. The integrated circuit device of claim 8, wherein between the substrate and the first interlevel dielectric layer, further comprising:
a second interlevel dielectric layer which is formed on the substrate; and
contact pads which are formed in the second interlevel dielectric layer and electrically connected to the contact plugs.

10. An integrated circuit device comprising:
an integrated circuit substrate in which source/drain regions are formed;
a first interlevel dielectric layer which is formed on the integrated circuit substrate;
gate line patterns which are formed in the first interlevel dielectric layer;
contact pads which are present between adjacent gate line patterns in the first interlevel dielectric layer and electrically connected to the source/drain regions;
a second interlevel dielectric layer which is formed on the first interlevel dielectric layer, wherein contact holes, through which the contact pads are exposed, are formed in the second interlevel dielectric layer;
first contact spacers which are formed along the side walls of the second interlevel dielectric layer which is exposed via the contact holes, the first contact spacers being formed of silicon oxide;
second contact spacers which are formed of silicon nitride and formed on the first contact spacers; and
contact plugs which are present in the contact holes between the second contact spacers.

11. The integrated circuit device of claim 10, wherein the second interlevel dielectric layer further comprises:
bit line contact plugs which are electrically connected to some of the contact pads; and
bit line patterns which are formed on the bit line contact plugs and electrically connected to the bit line contact plugs,
wherein the other contact pads, which are not electrically connected to the bit line contact plugs, are exposed through the contact holes.

12. A method of fabricating an integrated circuit device, comprising:
forming a first spacer having a first dielectric constant on a side wall of an interlevel dielectric layer that defines a contact hole in the interlevel dielectric layer;
forming a second spacer having a second dielectric constant that is greater than the first dielectric constant on the first spacer; and
forming a conductive contact in the hole.

13. A method according to claim 12 further comprising:
removing a portion of the second spacer from a bottom of the hole to expose the first spacer, wherein a remnant portion of the first spacer remain at the bottom; and
removing the remnant portion and the first spacer from the bottom to expose an underlying contact pad.

14. A method according to claim 12 wherein the first spacer comprises silicon nitride and the second spacer comprises silicon oxide.

15. A method according to claim 12 further comprising:
forming a conductive line in the interlevel dielectric layer adjacent the first spacer opposite the second spacer.

16. A method of fabricating an integrated circuit device, comprising:
forming a first interlevel dielectric layer on a substrate;
forming contact holes in the first interlevel dielectric layer;
forming first contact spacers along the side walls of the first interlevel dielectric layer which is exposed through the contact holes, the first contact spacers being formed of silicon oxide;
forming second contact spacers on the first contact spacers, using silicon nitride; and
forming contact plugs by filling a conductive material in the contact holes between the second contact spacers.

17. The method of claim 16, wherein the contact pads are formed of polysilicon or metal.

18. The method of claim 16, wherein the formation of the first and second contact spacers comprises:
forming a silicon oxide layer on the first interlevel dielectric layer conformally, the first interlevel dielectric layer including the contact holes;
forming a silicon nitride layer on the silicon oxide layer;
forming second contact spacers by etching the silicon nitride layer; and
forming first contact spacers by etching the silicon oxide layer.

19. The method of claim 18, wherein the formation of the silicon oxide layer is performed using atomic layer deposition (ALD) or chemical vapor deposition (CVD).

20. The method of claim 18, wherein the formation of the silicon nitride layer is performed using ALD or CVD.

21. The method of claim 18, after the formation of the first contact spacers, further comprising a process of eliminating remnant silicon nitride.

22. The method of claim 16, before the formation of the contact plugs further comprising a precleaning process.

23. The method of claim 22, wherein the precleaning process is performed using a chemical composition containing an agent that has excellent etching characteristics with respect to silicon oxide.

24. The method of claim 16, wherein the formation of the contact holes is performed using a photo mask of hole type or line type.

25. A method of fabricating an integrated circuit device, comprising:
forming gate line patterns on an integrated circuit substrate;
forming a first interlevel dielectric layer on the integrated circuit substrate and the gate line patterns;
forming contact pads on the first interlevel dielectric layer, the contact pads being electrically connected to a particular region of the integrated circuit substrate;
forming a second interlevel dielectric layer on the resultant structure;
forming contact holes on the second interlevel dielectric layer to expose the contact pads;
forming first contact spacers along the side walls of the second interlevel dielectric layer which is exposed through the contact holes, the first contact spacers being formed of silicon oxide;
forming second contact spacers on the first contact spacers, the second contact spacers being formed of silicon nitride; and
forming contact plugs by filling a conductive material in the contact holes between the second contact spacers.

26. The method of claim 25, after the formation of the second interlevel dielectric layer, further comprising:
forming bit line contact plugs and bit line patterns on the second interlevel dielectric layer, the bit line contact plugs being electrically connected to some of the contact pads; and
forming a third interlevel dielectric layer on the resultant structure,
wherein the contact holes are formed on the second and third interlevel dielectric layers so as to expose the other contact pads which are not connected to the bit line contact plugs.

27. The method of claim 26, wherein the formation of the first and second contact spacers comprise:
forming a silicon oxide layer on the first interlevel dielectric layer to match the first interlevel dielectric layer, the first interlevel dielectric layer including the contact holes;
forming a silicon nitride layer on the silicon oxide layer;
forming second contact spacers by etching the silicon nitride layer; and
forming first contact spacers by etching the silicon oxide layer.
